(19) United States
(12) Patent Application Publication
(10) Pub. No.: US 2026/0304858 A1
(43) Pub. Date: Oct. 1, 2026

(54) SEMICONDUCTOR DEVICE, SEMICONDUCTOR DEVICE MANUFACTURING METHOD, INVERTER CIRCUIT, DRIVE DEVICE, VEHICLE, AND ELEVATOR

(71) Applicants: Kabushiki Kaisha Toshiba, Kawasaki-shi (JP); National Institute of Advanced Industrial Science and Technology, Tokyo (JP)

(72) Inventors: Shinichi Kimoto, Tsukuba-shi Ibaraki (JP); Ryosuke Iijima, Setagaya Tokyo (JP); Shinsuke Harada, Tsukuba-shi Ibaraki (JP)

(73) Assignees: Kabushiki Kaisha Toshiba, Kawasaki-shi (JP); National Institute of Advanced Industrial Science and Technology, Tokyo (JP)

(21) Appl. No.: 19/537,675

(22) Filed: Feb. 12, 2026

Related U.S. Application Data
(63) Continuation of application No. PCT/JP2024/024266, filed on Jul. 4, 2024.

(30) Foreign Application Priority Data
Sep. 15, 2023 (JP) 2023-149720

(51) Int. Cl. H10D 62/10; B61C 3/00; B66B 11/04; H02P 27/06; H10D 30/01; H10D 30/66; H10D 62/00; H10D 62/832; H10P 30/20; H10P 30/22

(52) U.S. Cl. CPC H10D 62/109; H10D 30/0297; H10D 30/668; H10D 62/054; H10D 62/127; H10D 62/8325; H10P 30/2042; H10P 30/22; B61C 3/00; B66B 11/043; H02P 27/06

(57) ABSTRACT

A semiconductor device of embodiments includes: a silicon carbide layer having a first face and a second face; first and second trenches extending in a first direction; a gate electrode; a gate insulating layer; n-type first silicon carbide region; p-type second silicon carbide region between the first silicon carbide region and the first face and shallower than the trenches; n-type third silicon carbide regions and p-type fourth silicon carbide regions disposed between the second silicon carbide region and the first face and formed alternately in the first direction; n-type fifth silicon carbide region between the first trench and the second trench and between the second silicon carbide region and third silicon carbide regions and the fourth silicon carbide regions, and extending in the first direction; and a n-type sixth silicon carbide region spaced apart from the fifth silicon carbide region, and extending in the first direction.

### CROSS-REFERENCE TO RELATED APPLICATION

This application is based upon and claims the benefit of priority from Japanese Patent Application No. 2023-149720, filed on Sep. 15, 2023, and the International Application PCT/JP2024/024266, filed Jul. 4, 2024, the entire contents of which are incorporated herein by reference.

### FIELD

Embodiments described herein relate generally to a semiconductor device, a semiconductor device manufacturing method, an inverter circuit, a drive device, a vehicle, and an elevator.

### BACKGROUND

Silicon carbide (SiC) is expected as a material for next-generation semiconductor devices. Silicon carbide has excellent physical properties, such as a bandgap of about 3 times that of silicon, a breakdown field strength of about 10 times that of silicon, and a thermal conductivity of about 3 times that of silicon. By using such physical properties, it is possible to realize a semiconductor device that can operate at high temperature with low loss.

In a vertical metal oxide semiconductor field effect transistor (MOSFET) using silicon carbide, a trench gate structure in which a gate electrode is provided in a trench is applied in order to realize a low on-resistance. By applying the trench gate structure, the channel area per unit area is increased, and accordingly, the on-resistance is reduced.

### BRIEF DESCRIPTION OF THE DRAWINGS

FIG. 1 is a schematic cross-sectional view of a semiconductor device according to a first embodiment;

FIG. 2 is a schematic top view of the semiconductor device according to the first embodiment;

FIG. 3 is a schematic cross-sectional view of the semiconductor device according to the first embodiment;

FIG. 4 is a schematic cross-sectional view of the semiconductor device according to the first embodiment;

FIG. 5 is a schematic cross-sectional view showing an example of a semiconductor device manufacturing method according to the first embodiment;

FIG. 6 is a schematic cross-sectional view showing an example of the semiconductor device manufacturing method according to the first embodiment;

FIG. 7 is a schematic cross-sectional view showing an example of the semiconductor device manufacturing method according to the first embodiment;

FIG. 8 is a schematic cross-sectional view showing an example of the semiconductor device manufacturing method according to the first embodiment;

FIG. 9 is a schematic cross-sectional view showing an example of the semiconductor device manufacturing method according to the first embodiment;

FIG. 10 is a schematic cross-sectional view showing an example of the semiconductor device manufacturing method according to the first embodiment;

FIG. 11 is a schematic cross-sectional view showing an example of the semiconductor device manufacturing method according to the first embodiment;

FIG. 12 is a schematic cross-sectional view showing an example of the semiconductor device manufacturing method according to the first embodiment;

FIG. 13 is a schematic cross-sectional view showing an example of the semiconductor device manufacturing method according to the first embodiment;

FIG. 14 is a schematic cross-sectional view showing an example of the semiconductor device manufacturing method according to the first embodiment;

FIG. 15 is a schematic cross-sectional view showing an example of the semiconductor device manufacturing method according to the first embodiment;

FIG. 16 is a schematic cross-sectional view of a semiconductor device according to a first comparative example;

FIG. 17 is an explanatory diagram of a problem of the semiconductor device according to the first comparative example;

FIG. 18 is a schematic cross-sectional view of a semiconductor device according to a second comparative example;

FIG. 19 is an explanatory diagram of a problem of the semiconductor device according to the second comparative example;

FIG. 20 is an explanatory diagram of the function and effect of the semiconductor device according to the first embodiment;

FIG. 21 is a schematic cross-sectional view of a semiconductor device according to a second embodiment;

FIG. 22 is a schematic cross-sectional view of the semiconductor device according to the second embodiment;

FIG. 23 is a schematic cross-sectional view of a semiconductor device according to a modification example of the second embodiment;

FIG. 24 is a schematic diagram of a drive device according to a third embodiment;

FIG. 25 is a schematic diagram of a vehicle according to a fourth embodiment;

FIG. 26 is a schematic diagram of a vehicle according to a fifth embodiment; and

FIG. 27 is a schematic diagram of an elevator according to a sixth embodiment.

### DETAILED DESCRIPTION

A semiconductor device of embodiments includes: a silicon carbide layer having a first face parallel to a first direction and a second direction perpendicular to the first direction and a second face parallel to the first face; a first trench provided in the silicon carbide layer, provided on a side of the first face of the silicon carbide layer, and extending in the first direction; a first gate electrode provided in the first trench; a first gate insulating layer provided between the first gate electrode and the silicon carbide layer; a second trench provided in the silicon carbide layer, provided on the side of the first face of the silicon carbide layer, and extending in the first direction; a second gate electrode provided in the second trench; a second gate insulating layer provided between the second gate electrode and the silicon carbide layer; a first silicon carbide region of n-type provided in the silicon carbide layer, at least a part of the first silicon carbide region of n-type being provided between the first trench and the second trench; a second silicon carbide region of p-type provided in the silicon carbide layer, provided between the first trench and the second trench, and provided between the first silicon carbide region and the first face; a plurality of third silicon carbide regions of n-type and a plurality of fourth silicon carbide regions of p-type provided in the silicon carbide layer, provided between the first trench and the second trench, provided between the second silicon carbide region and the first face, and arranged alternately in the first direction; a fifth silicon carbide region of n-type provided in the silicon carbide layer, provided between the first trench and the second trench, in contact with the first trench, provided between the second silicon carbide region and the third silicon carbide region and between the second silicon carbide region and the fourth silicon carbide region, and extending in the first direction; a sixth silicon carbide region of n-type provided in the silicon carbide layer, provided between the first trench and the second trench, in contact with the second trench, spaced apart from the fifth silicon carbide region, provided between the second silicon carbide region and the third silicon carbide region and between the second silicon carbide region and the fourth silicon carbide region, and extending in the first direction; a first electrode provided on a side of the first face with respect to the silicon carbide layer and in contact with the third silicon carbide region and the fourth silicon carbide region; a second electrode provided on a side of the second face with respect to the silicon carbide layer; and an interlayer insulating layer provided between the first gate electrode and the first electrode and between the second gate electrode and the first electrode.

Hereinafter, embodiments will be described with reference to the accompanying diagrams. In the following description, the same or similar members and the like will be denoted by the same reference numerals, and the description of the members and the like once described will be omitted as appropriate.

In addition, in the following description, when the notations of n⁺, n, n⁻, p⁺, p, and p⁻ are used, these notations indicate the relative high and low of the impurity concentration in each conductive type. That is, n⁺ indicates that the n-type impurity concentration is relatively higher than n, and n⁻ indicates that the n-type impurity concentration is relatively lower than n. In addition, p⁺ indicates that the p-type impurity concentration is relatively higher than p, and p⁻ indicates that the p-type impurity concentration is relatively lower than p. In addition, n⁺-type and n⁻-type may be simply described as n-type, and p⁺-type and p⁻-type may be simply described as p-type.

The impurity concentration can be measured by, for example, secondary ion mass spectrometry (SIMS). In addition, the relative high and low of the impurity concentration can be determined from, for example, the high and low of the carrier concentration obtained by scanning capacitance microscopy (SCM). In addition, the distance such as the width or depth of an impurity region can be calculated by, for example, SIMS. In addition, the distance such as the width or depth of an impurity region can be calculated from, for example, an SCM image.

The width of a trench, the distance between trenches, the depth of a trench, the thickness of an insulating layer, and the like can be measured, for example, on an image of transmission electron microscope (TEM).

In this specification, the impurity concentration in a specific region is represented by the impurity concentration in the central portion of the corresponding region, unless otherwise defined.

### First Embodiment

A semiconductor device according to a first embodiment includes: a silicon carbide layer having a first face parallel to a first direction and a second direction perpendicular to the first direction and a second face parallel to the first face; a first trench provided in the silicon carbide layer, provided on a side of the first face of the silicon carbide layer, and extending in the first direction; a first gate electrode provided in the first trench; a first gate insulating layer provided between the first gate electrode and the silicon carbide layer; a second trench provided in the silicon carbide layer, provided on the side of the first face of the silicon carbide layer, and extending in the first direction; a second gate electrode provided in the second trench; a second gate insulating layer provided between the second gate electrode and the silicon carbide layer; a first silicon carbide region of n-type provided in the silicon carbide layer, at least a part of the first silicon carbide region of n-type being provided between the first trench and the second trench; a second silicon carbide region of p-type provided in the silicon carbide layer, provided between the first trench and the second trench, and provided between the first silicon carbide region and the first face; a plurality of third silicon carbide regions of n-type and a plurality of fourth silicon carbide regions of p-type provided in the silicon carbide layer, provided between the first trench and the second trench, provided between the second silicon carbide region and the first face, and arranged alternately in the first direction; a fifth silicon carbide region of n-type provided in the silicon carbide layer, provided between the first trench and the second trench, in contact with the first trench, provided between the second silicon carbide region and the third silicon carbide region and between the second silicon carbide region and the fourth silicon carbide region, and extending in the first direction; a sixth silicon carbide region of n-type provided in the silicon carbide layer, provided between the first trench and the second trench, in contact with the second trench, spaced apart from the fifth silicon carbide region, provided between the second silicon carbide region and the third silicon carbide region and between the second silicon carbide region and the fourth silicon carbide region, and extending in the first direction; a first electrode provided on a side of the first face with respect to the silicon carbide layer and in contact with the third silicon carbide region and the fourth silicon carbide region; a second electrode provided on a side of the second face with respect to the silicon carbide layer; and an interlayer insulating layer provided between the first gate electrode and the first electrode and between the second gate electrode and the first electrode.

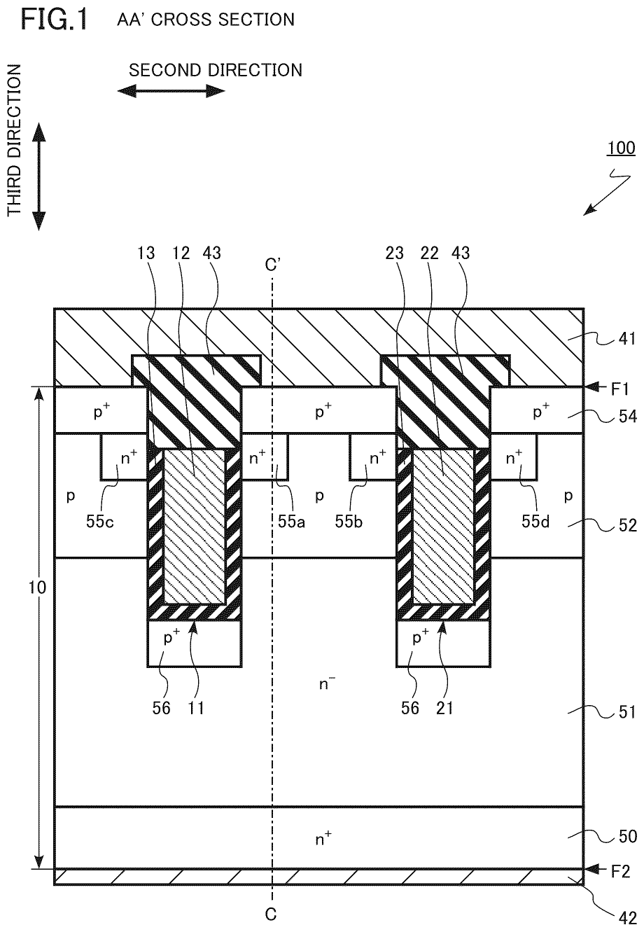

FIG. 1 is a schematic cross-sectional view of the semiconductor device according to the first embodiment. The semiconductor device according to the first embodiment is a trench gate type vertical MOSFET 100 using silicon carbide. The MOSFET 100 is an n-channel MOSFET having electrons as carriers.

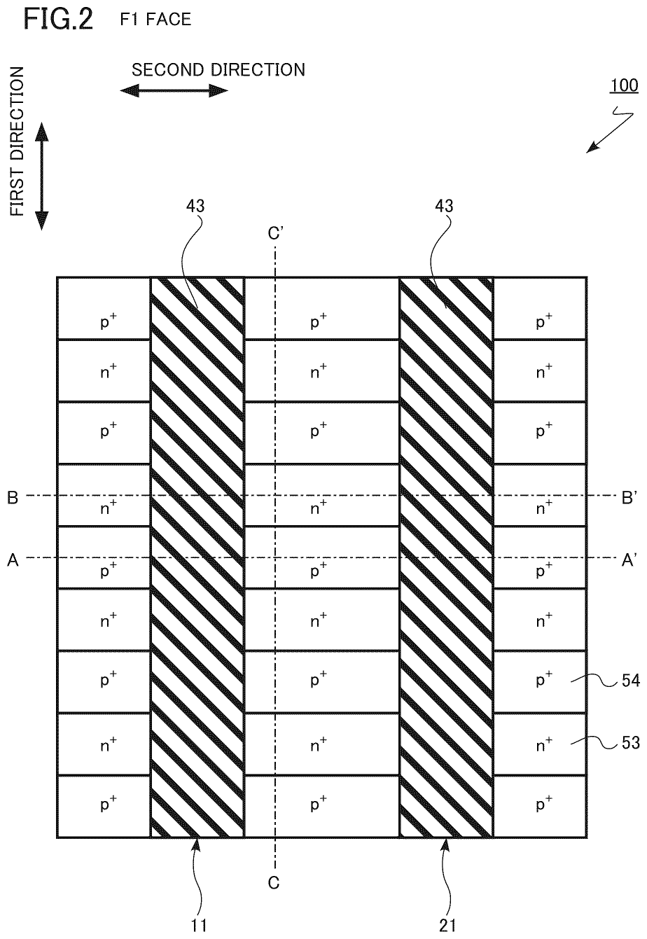

FIG. 2 is a schematic top view of the semiconductor device according to the first embodiment. FIG. 2 is a top view on a first face F1 in FIG. 1. FIG. 1 is a cross-sectional view taken along the line AA′ of FIG. 2.

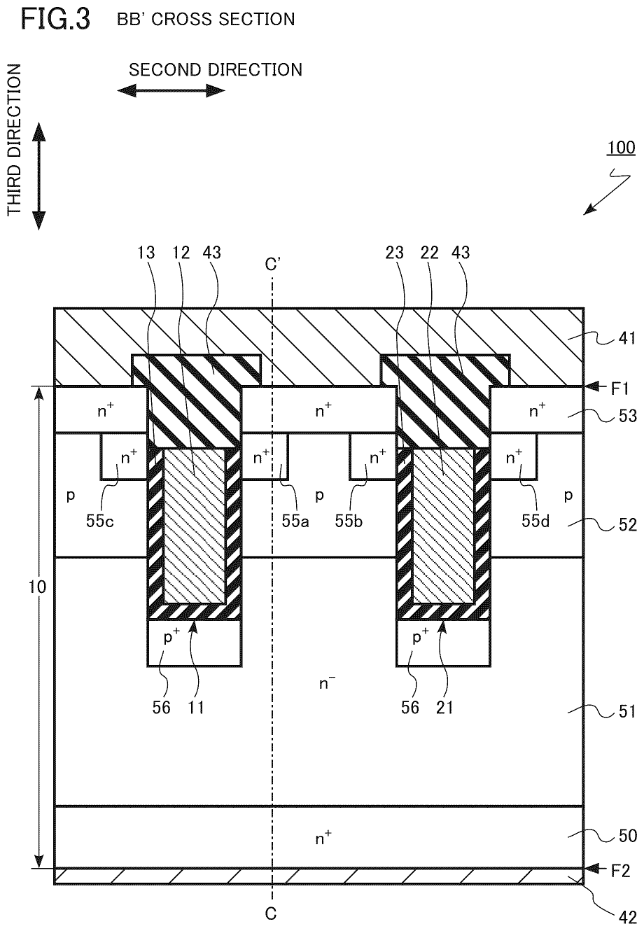

FIG. 3 is a schematic cross-sectional view of the semiconductor device according to the first embodiment. FIG. 3 is a cross-sectional view taken along the line BB′ of FIG. 2.

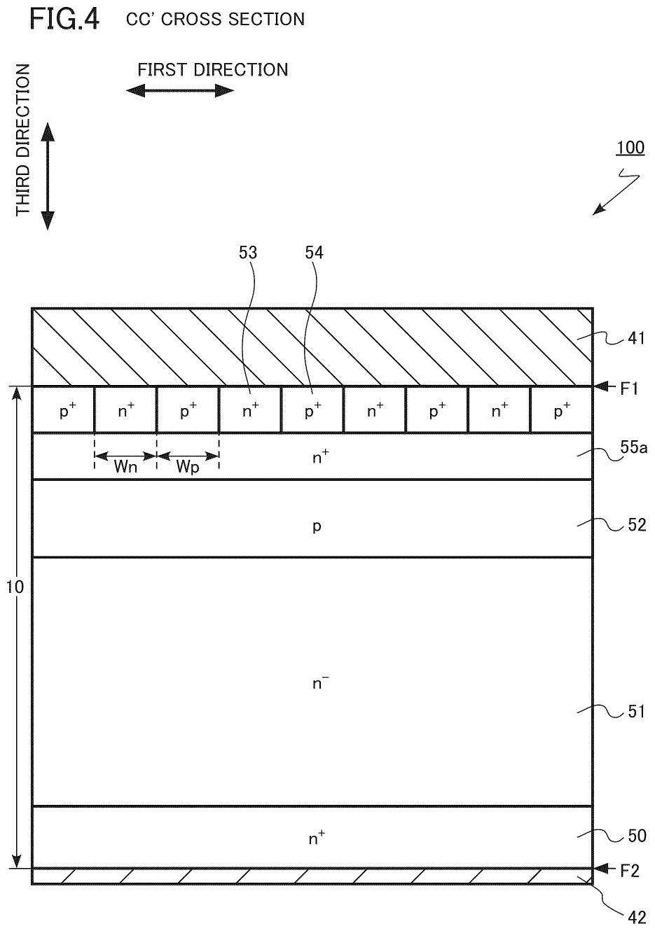

FIG. 4 is a schematic cross-sectional view of the semiconductor device according to the first embodiment. FIG. 4 is a cross-sectional view taken along the line CC′ of FIGS. 1, 2, and 3.

The MOSFET 100 includes a silicon carbide layer 10, a first trench 11, a first gate electrode 12, a first gate insulating layer 13, a second trench 21, a second gate electrode 22, a second gate insulating layer 23, a source electrode 41 (first electrode), a drain electrode 42 (second electrode), and an interlayer insulating layer 43.

Hereinafter, the first trench 11 and the second trench 21 may be collectively referred to as a trench. In addition, the first gate electrode 12 and the second gate electrode 22 may be collectively referred to as a gate electrode. In addition, the first gate insulating layer 13 and the second gate insulating layer 23 may be collectively referred to as a gate insulating layer.

In the silicon carbide layer 10, an n⁺-type drain region 50, an n⁻-type drift region 51 (first silicon carbide region), a p-type body region 52 (second silicon carbide region), an n⁺-type upper source region 53 (third silicon carbide region), a p⁺-type contact region 54 (fourth silicon carbide region), a first lower source region 55a (fifth silicon carbide region) of n⁺-type, a second lower source region 55b (sixth silicon carbide region) of n⁺-type, a third lower source region 55c of n⁺-type, a fourth lower source region 55d of n⁺-type, and a p⁺-type electric field relaxation region 56 are provided.

Hereinafter, the first lower source region 55a, the second lower source region 55b, the third lower source region 55c, and the fourth lower source region 55d may be collectively referred to as a lower source region 55.

The silicon carbide layer 10 is a single crystal SiC. The silicon carbide layer 10 is, for example, 4H-SiC.

The silicon carbide layer 10 includes a first face (“F1” in FIG. 1) and a second face (“F2” in FIG. 1). The first face F1 and the second face F2 face each other. The first face F1 and the second face F2 are parallel to each other. Hereinafter, the first face F1 is also referred to as a surface, and the second face F2 is also referred to as a back surface. Hereinafter, the “depth” means a depth in a direction toward the second face F2 with the first face F1 as a reference.

In FIGS. 1 to 4, the first direction and the second direction are directions parallel to the first face F1. In addition, the second direction is a direction perpendicular to the first direction.

In FIGS. 1 to 4, the third direction is a direction perpendicular to the first direction and the second direction. The third direction is a direction from the first face F1 to the second face F2. The third direction is a direction perpendicular to the first face F1. Hereinafter, the third direction may be referred to as a depth direction.

The first face F1 is, for example, a face inclined by an angle equal to or more than 0° and equal to or less than 8° with respect to the (0001) face. That is, the first face F1 is a face whose normal is inclined by an angle equal to or more than 0° and equal to or less than 8° with respect to the c axis in the [0001] direction. In other words, an off angle with respect to the (0001) face is equal to or more than 0° and equal to or less than 8°. In addition, the second face F2 is, for example, a face inclined by an angle equal to or more than 0° and equal to or less than 8° with respect to the (000-1) face.

The (0001) face is referred to as a silicon face. The (000-1) face is referred to as a carbon face. The inclination direction of the first face F1 and the second face F2 is, for example, a [11-20] direction. The [11-20] direction is an a-axis direction. In FIG. 2, for example, the first direction shown in the diagram is the a-axis direction.

The first trench 11 and the second trench 21 are present in the silicon carbide layer 10. The first trench 11 and the second trench 21 are provided on the surface side of the silicon carbide layer 10. The first trench 11 and the second trench 21 extend in the first direction as shown in FIG. 2. The first trench 11 and the second trench 21 are grooves formed in the silicon carbide layer 10.

The widths of the first trench 11 and the second trench 21 in the second direction are smaller than, for example, the distance between the first trench 11 and the second trench 21.

The widths of the first trench 11 and the second trench 21 in the second direction are, for example, equal to or more than 0.3 μm and equal to or less than 1 μm. The distance between the first trench 11 and the second trench 21 is, for example, equal to or more than 0.5 μm and equal to or less than 2 μm. The depths of the first trench 11 and the second trench 21 are, for example, equal to or more than 1 μm and equal to or less than 3 μm.

A plurality of trenches including the first trench 11 and the second trench 21 are repeatedly arranged in the second direction. The pitch between the plurality of trenches in the second direction is, for example, equal to or more than 1 μm and equal to or less than 5 μm.

The first gate electrode 12 is provided in the first trench 11. The first gate electrode 12 is provided between the source electrode 41 and the drain electrode 42. The first gate electrode 12 extends in the first direction.

The distance in the third direction, which is perpendicular to the first face F1, from the first face F1 to the first gate electrode 12 is, for example, larger than the distance from the first face F1 to the interface between the contact region 54 and the first lower source region 55a. In addition, the distance in the third direction, which is perpendicular to the first face F1, from the first face F1 to the first gate electrode 12 is, for example, smaller than the distance from the first face F1 to the interface between the first lower source region 55a and the body region 52.

The second gate electrode 22 is provided in the second trench 21. The second gate electrode 22 is provided between the source electrode 41 and the drain electrode 42. The second gate electrode 22 extends in the first direction.

The distance in the third direction, which is perpendicular to the first face F1, from the first face F1 to the second gate electrode 22 is, for example, larger than the distance from the first face F1 to the interface between the contact region 54 and the second lower source region 55b. In addition, the distance in the third direction, which is perpendicular to the first face F1, from the first face F1 to the second gate electrode 22 is, for example, smaller than the distance from the first face F1 to the interface between the second lower source region 55b and the body region 52.

The first gate electrode 12 and the second gate electrode 22 are conductive layers. The first gate electrode 12 and the second gate electrode 22 are, for example, polycrystalline silicon containing p-type impurities or n-type impurities.

The first gate insulating layer 13 is provided between the first gate electrode 12 and the silicon carbide layer 10. The first gate insulating layer 13 is provided between the first gate electrode 12 and each of the first lower source region 55a, the third lower source region 55c, the body region 52, the drift region 51, and the electric field relaxation region 56.

The second gate insulating layer 23 is provided between the second gate electrode 22 and the silicon carbide layer 10. The second gate insulating layer 23 is provided between the second gate electrode 22 and each of the second lower source region 55b, the fourth lower source region 55d, the body region 52, the drift region 51, and the electric field relaxation region 56.

The first gate insulating layer 13 and the second gate insulating layer 23 are, for example, silicon oxide films. For example, a High-k insulating film (high dielectric constant insulating film, such as HfSiON, ZrSiON, and AlON) can be applied to the first gate insulating layer 13 and the second gate insulating layer 23. In addition, for example, a stacked film of a silicon oxide film (SiO₂) and a High-K insulating film can also be applied to the first gate insulating layer 13 and the second gate insulating layer 23.

The interlayer insulating layer 43 is provided on the first gate electrode 12 and on the second gate electrode 22. The interlayer insulating layer 43 is provided between the first gate electrode 12 and the source electrode 41 and between the second gate electrode 22 and the source electrode 41.

The interlayer insulating layer 43 is, for example, a silicon oxide film.

The source electrode 41 is provided on the surface side of the silicon carbide layer 10. The source electrode 41 is provided on the surface of the silicon carbide layer 10. The source electrode 41 is electrically connected to the body region 52, the upper source region 53, the lower source region 55, and the contact region 54. The source electrode 41 is in contact with the upper source region 53 and the contact region 54.

The source electrode 41 contains metal. The metal forming the source electrode 41 is, for example, a stacked structure of titanium (Ti) and aluminum (Al). The source electrode 41 may contain metal silicide or metal carbide in contact with the silicon carbide layer 10.

The drain electrode 42 is provided on the back surface side of the silicon carbide layer 10. The drain electrode 42 is provided on the back surface of the silicon carbide layer 10. The drain electrode 42 is in contact with the drain region 50.

The drain electrode 42 is, for example, a metal or a metal semiconductor compound. The drain electrode 42 contains a material selected from a group consisting of nickel silicide (NiSi), titanium (Ti), nickel (Ni), silver (Ag), and gold (Au), for example.

The n⁺-type drain region 50 is provided on the back surface side of the silicon carbide layer 10. The drain region 50 contains, for example, nitrogen (N) as an n-type impurity. The n-type impurity concentration of the drain region 50 is, for example, equal to or more than 1×10¹⁸ cm⁻³ and equal to or less than 1×10²¹ cm⁻³.

The n⁻-type drift region 51 is provided on the drain region 50. The drift region 51 is provided between the drain region 50 and the surface of the silicon carbide layer 10. A part of the drift region 51 is provided between the first trench 11 and the second trench 21.

The drift region 51 contains, for example, nitrogen (N) as an n-type impurity. The n-type impurity concentration of the drift region 51 is, for example, equal to or more than 4×10¹⁴ cm⁻³ and equal to or less than 1×10¹⁸ cm⁻³. The thickness of the drift region 51 in the third direction is, for example, equal to or more than 4 μm and equal to or less than 150 μm.

The p-type body region 52 is provided between the drift region 51 and the surface of the silicon carbide layer 10. The body region 52 is provided between the first trench 11 and the second trench 21. The body region 52 is in contact with the side surface of the first trench 11 and the side surface of the second trench 21.

The body region 52 functions as a channel region of the MOSFET 100. For example, when the MOSFET 100 is turned on, a channel through which electrons flow is formed in a region of the body region 52 in contact with the gate insulating layer.

The depth of the body region 52 is smaller than the depth of the first trench 11 from the surface of the silicon carbide layer 10. The first trench 11 penetrates the body region 52. The depth of the body region 52 is smaller than the depth of the second trench 21 from the surface of the silicon carbide layer 10. The second trench 21 penetrates the body region 52. The depth of the body region 52 is, for example, equal to or more than 0.8 μm and equal to or less than 2.0 μm.

The body region 52 contains, for example, aluminum (Al) as a p-type impurity. The p-type impurity concentration of the body region 52 is, for example, equal to or more than 5×10¹⁶ cm⁻³ and equal to or less than 5×10¹⁸ cm⁻³.

The n⁺-type upper source region 53 and the p⁺-type contact region 54 are provided between the first trench 11 and the second trench 21. The upper source region 53 and the contact region 54 are provided between the body region 52 and the surface of the silicon carbide layer 10.

As shown in FIG. 2, a plurality of upper source regions 53 and a plurality of contact regions 54 are alternately arranged in the first direction. The upper source region 53 and the contact region 54 are in contact with each other.

The upper source region 53 extends in the second direction so as to cross the trench. The contact region 54 extends in the second direction so as to cross the trench.

The width (Wn in FIG. 4) of the upper source region 53 in the first direction is, for example, equal to or more than 0.3 μm and equal to or less than 30 μm. The width (Wp in FIG. 4) of the contact region 54 in the first direction is, for example, equal to or more than 0.3 μm and equal to or less than 30 μm. The width Wn of the upper source region 53 in the first direction is, for example, equal to or more than 0.5 times and equal to or less than 2 times the width Wp of the contact region 54 in the first direction.

The arrangement ratio (Wp/(Wn+Wp)) of the contact region 54 in the first direction is, for example, equal to or more than 0.1 and equal to or less than 50. In other words, the ratio (Wp/(Wn+Wp)) of the width Wp of the contact region 54 in the first direction to the sum of the width Wn of the upper source region 53 in the first direction and the width Wp of the contact region 54 in the first direction is, for example, equal to or more than 0.1 and equal to or less than 50.

The upper source region 53 is in contact with the side surface of the trench. The upper source region 53 is in contact with, for example, the side surface of the first trench 11. The upper source region 53 is in contact with, for example, the side surface of the second trench 21.

The upper source region 53 is in contact with the source electrode 41. The upper source region 53 is in contact with the source electrode 41 on the surface of the silicon carbide layer 10, for example.

The depth of the upper source region 53 is smaller than the depth of the body region 52. The depth of the upper source region 53 is, for example, equal to or more than 0.2 μm and equal to or less than 0.6 μm.

The upper source region 53 contains nitrogen (N) or phosphorus (P) as an n-type impurity. The n-type impurity concentration of the upper source region 53 is higher than the n-type impurity concentration of the drift region 51. The n-type impurity concentration of the upper source region 53 is, for example, equal to or more than 1×10¹⁹ cm⁻³ and equal to or less than 1×10²¹cm⁻³.

The p⁺-type contact region 54 is in contact with the side surface of the trench. The contact region 54 is in contact with, for example, the side surface of the first trench 11. The contact region 54 is in contact with, for example, the side surface of the second trench 21.

The contact region 54 is in contact with the source electrode 41. The contact region 54 is in contact with the source electrode 41 on the surface of the silicon carbide layer 10, for example.

The depth of the contact region 54 is smaller than the depth of the body region 52. The depth of the contact region 54 is, for example, equal to or more than 0.2 μm and equal to or less than 0.6 μm.

The contact region 54 contains, for example, aluminum (Al) as a p-type impurity. The p-type impurity concentration of the contact region 54 is higher than the p-type impurity concentration of the body region 52, for example.

The p-type impurity concentration of the contact region 54 is, for example, equal to or more than 1×10¹⁸ cm⁻³ and equal to or less than 1×10²¹cm⁻³. In addition, the p-type impurity concentration of a portion of the contact region 54 in contact with the source electrode 41 is, for example, equal to or more than 1×10¹⁹ cm⁻³ and equal to or less than 1×10²¹cm⁻³.

The first lower source region 55a of n⁺-type is provided between the body region 52 and the upper source region 53. The first lower source region 55a is provided between the body region 52 and the contact region 54.

The first lower source region 55a is in contact with the body region 52. The first lower source region 55a is in contact with the upper source region 53. The first lower source region 55a is in contact with the contact region 54.

The first lower source region 55a extends in the first direction.

The first lower source region 55a is provided between the first trench 11 and the second trench 21. The first lower source region 55a is in contact with the side surface of the second trench 21.

The second lower source region 55b of n⁺-type is provided between the body region 52 and the upper source region 53. The second lower source region 55b is provided between the body region 52 and the contact region 54.

The second lower source region 55b is in contact with the body region 52. The second lower source region 55b is in contact with the upper source region 53. The second lower source region 55b is in contact with the contact region 54.

The second lower source region 55b extends in the first direction.

The second lower source region 55b is spaced apart from the first lower source region 55a in the second direction. The body region 52 is provided between the first lower source region 55a and the second lower source region 55b.

The third lower source region 55c of n⁺-type is provided between the body region 52 and the upper source region 53. The third lower source region 55c is provided between the body region 52 and the contact region 54.

The third lower source region 55c is in contact with the body region 52. The third lower source region 55c is in contact with the upper source region 53. The third lower source region 55c is in contact with the contact region 54.

The third lower source region 55c extends in the first direction.

The first trench 11 is provided between the first lower source region 55a and the third lower source region 55c. The third lower source region 55c is in contact with the side surface of the first trench 11.

The fourth lower source region 55d of n⁺-type is provided between the body region 52 and the upper source region 53. The fourth lower source region 55d is provided between the body region 52 and the contact region 54.

The fourth lower source region 55d is in contact with the body region 52. The fourth lower source region 55d is in contact with the upper source region 53. The fourth lower source region 55d is in contact with the contact region 54.

The fourth lower source region 55d extends in the first direction.

The second trench 21 is provided between the second lower source region 55b and the fourth lower source region 55d. The fourth lower source region 55d is in contact with the side surface of the second trench 21.

The depth of the lower source region 55 is smaller than the depth of the body region 52. The depth of the lower source region 55 is larger than the depth of the upper source region 53 and the depth of the contact region 54. The depth of the lower source region 55 is, for example, equal to or more than 0.4 μm and equal to or less than 1.0 μm.

The width of the lower source region 55 in the third direction is, for example, equal to or more than 0.2 μm and equal to or less than 0.6 μm.

The lower source region 55 contains nitrogen (N) or phosphorus (P) as an n-type impurity. The n-type impurity concentration of the lower source region 55 is higher than the n-type impurity concentration of the drift region 51. The n-type impurity concentration of the lower source region 55 is, for example, equal to or more than 1×10¹⁹ cm⁻³ and equal to or less than 1×10²¹cm⁻³.

The n-type impurity concentration of the lower source region 55 is, for example, equal to or more than 0.1 times and equal to or less than 10 times the n-type impurity concentration of the upper source region 53.

The p⁺-type electric field relaxation region 56 is provided between the drift region 51 and the trench. The electric field relaxation region 56 is provided, for example, between the drift region 51 and the first trench 11. The electric field relaxation region 56 is provided, for example, between the drift region 51 and the second trench 21.

The electric field relaxation region 56 is in contact with the first trench 11. The electric field relaxation region 56 is in contact with the second trench 21.

The electric field relaxation region 56 contains, for example, aluminum (Al) as a p-type impurity. The p-type impurity concentration of the electric field relaxation region 56 is higher than the p-type impurity concentration of the body region 52, for example. The p-type impurity concentration of the electric field relaxation region 56 is, for example, equal to or more than 1×10¹⁷ cm⁻³ and equal to or less than 1×10²⁰cm⁻³.

The electric potential of the electric field relaxation region 56 is fixed to, for example, the electric potential of the source electrode 41. The electric potential of the electric field relaxation region 56 is fixed to, for example, the source electric potential. The electric field relaxation region 56 has a function of reducing the electric field applied to the gate insulating layer at the bottom of the trench.

A semiconductor device manufacturing method according to the first embodiment includes: preparing a silicon carbide layer having a first face parallel to a first direction and a second direction perpendicular to the first direction and a second face parallel to the first face and including a first region of n-type, a second region of p-type provided between the first region and the first face, and a plurality of third regions of n-type and a plurality of fourth regions of p-type provided between the second region and the first face, arranged alternately in the first direction, and extending in the second direction; forming a first mask material having a first opening extending in the first direction on the silicon carbide layer; forming a fifth region of n-type deeper than the third region and the fourth region and shallower than the second region by ion-implanting n-type impurities through the first opening using the first mask material as a mask; forming a sidewall at the first opening; forming a trench penetrating the second region, the third region, the fourth region, and the fifth region using the first mask material and the sidewall as a mask; forming a gate insulating layer in the trench; and forming a gate electrode on the gate insulating layer in the trench.

Hereinafter, an example of a semiconductor device manufacturing method according to the first embodiment will be described.

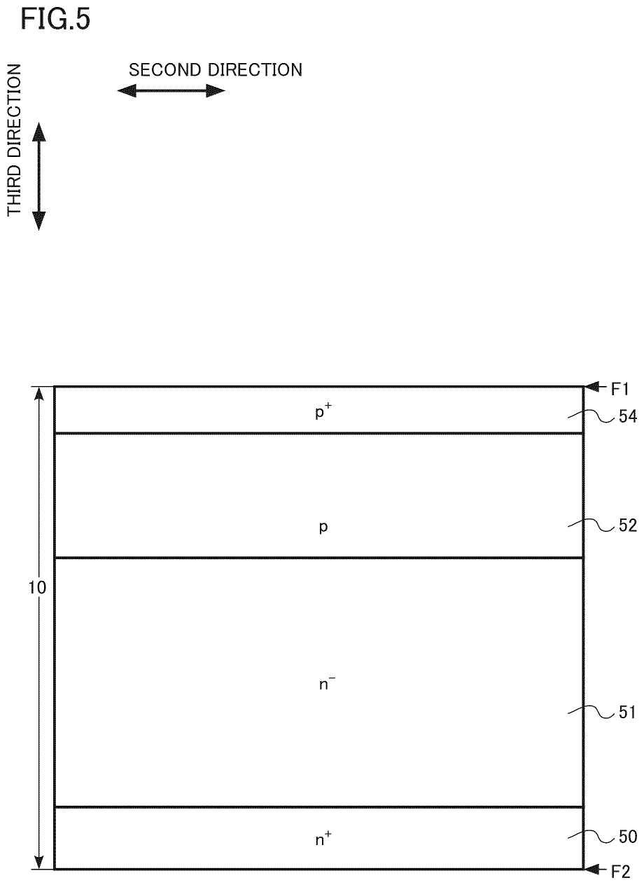

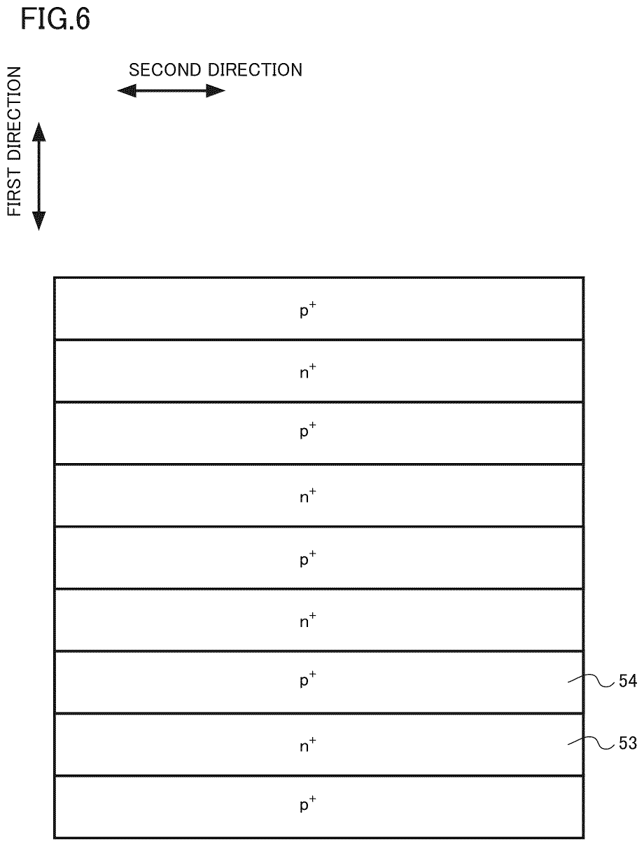

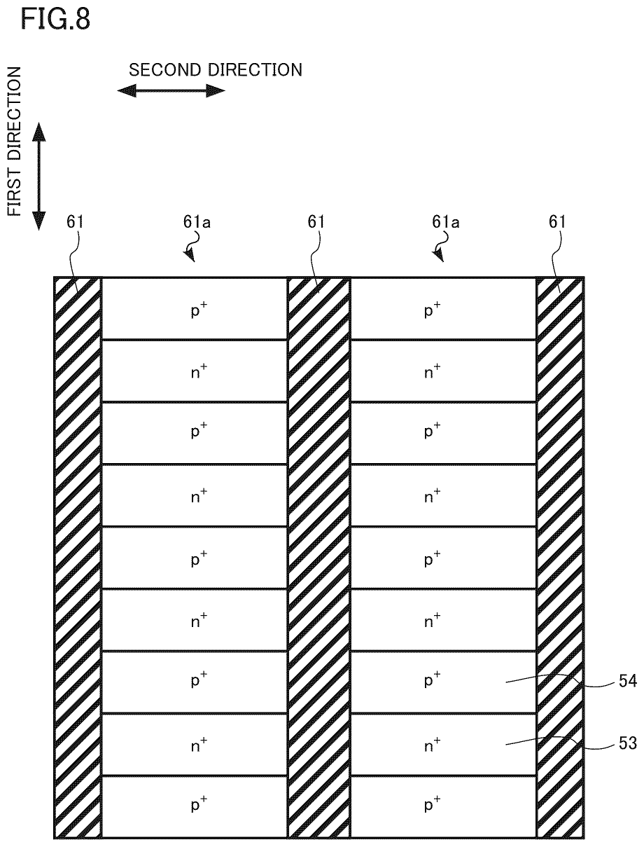

FIGS. 5 to 15 are schematic cross-sectional views showing an example the semiconductor device manufacturing method according to the first embodiment. FIGS. 5, 7, 9, 10, 11, 12, 13, 14, and 15 are cross-sectional views corresponding to FIG. 1. FIGS. 6 and 8 are top views corresponding to FIG. 2.

First, the silicon carbide layer 10 is prepared (FIGS. 5 and 6). The silicon carbide layer 10 has a first face (F1 in FIG. 5) parallel to the first direction and the second direction perpendicular to the first direction and a second face (F2 in FIG. 5) parallel to the first face F1.

The silicon carbide layer 10 includes an n⁺-type drain region 50, an n⁻-type drift region 51 (first region), a p-type body region 52 (second region), a plurality of n⁺-type upper source regions 53 (third region), and a plurality of p⁺-type contact regions 54 (fourth region).

The body region 52 is provided between the drain region 50 and the first face F1. The upper source region 53 and the contact region 54 are provided between the body region 52 and the first face F1.

The upper source region 53 and the contact region 54 are alternately arranged in the first direction as shown in FIG. 6. The upper source region 53 and the contact region 54 extend in the second direction as shown in FIG. 6.

The drift region 51 is formed on the drain region 50 by using an epitaxial growth method, for example. The body region 52, the upper source region 53, and the contact region 54 are formed by, for example, ion implantation of impurities from the surface of the silicon carbide layer 10.

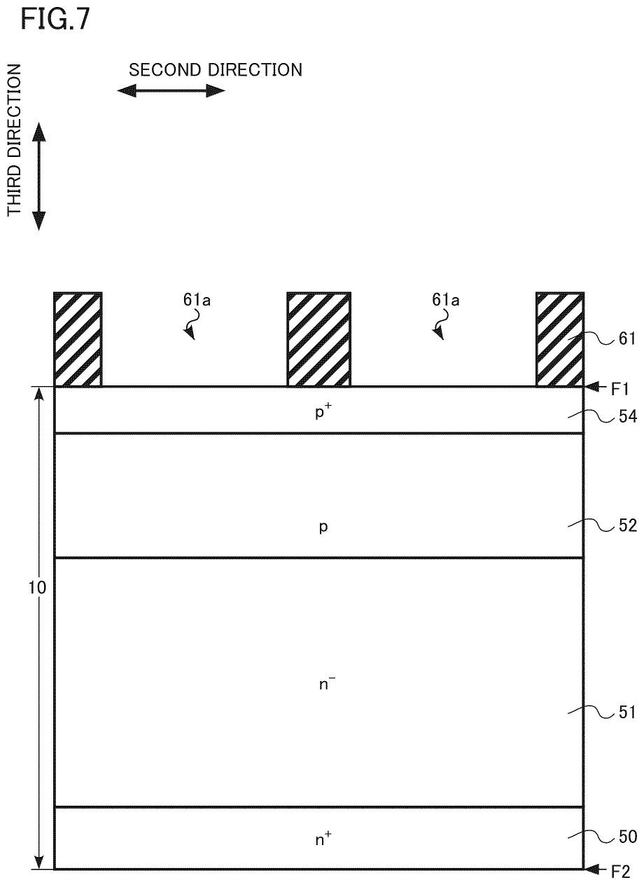

Then, a first mask material 61 is formed on the silicon carbide layer 10 (FIGS. 7 and 8). The first mask material 61 has a first opening 61a. The first opening 61a extends in the first direction. In the first opening 61a, the upper source region 53 and the contact region 54 are exposed.

The first mask material 61 is formed, for example, by depositing a film using a chemical vapor deposition method (CVD method) and patterning the film using a lithography method and a reactive ion etching method (RIE method). The first mask material 61 is, for example, a silicon oxide film.

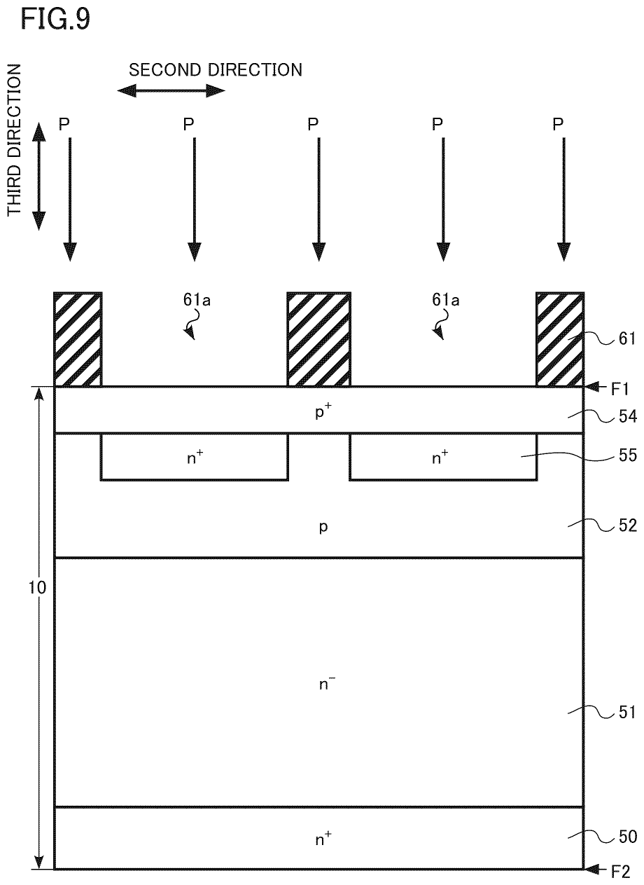

Then, using first mask material 61 as a mask, n-type impurities are ion-implanted into the silicon carbide layer 10 through the first opening 61a to form the n⁺-type lower source region 55 (fifth region) (FIG. 9). The n-type impurity is, for example, phosphorus (P) or nitrogen (N).

The lower source region 55 is shallower than the body region 52. The lower source region 55 is deeper than the upper source region 53 and the contact region 54.

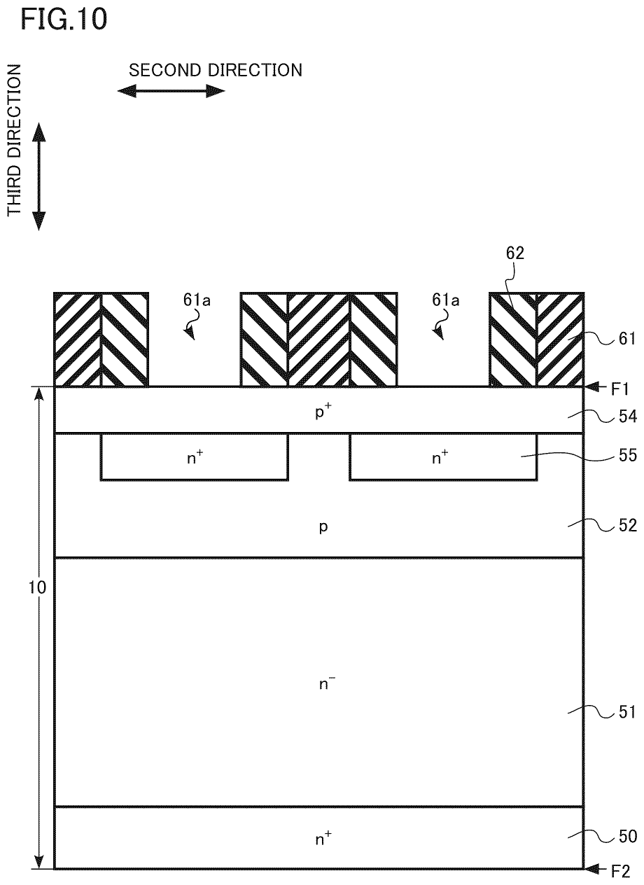

Then, a sidewall 62 is formed in the first opening 61a of the first mask material 61 (FIG. 10). The sidewall 62 is, for example, a silicon oxide film.

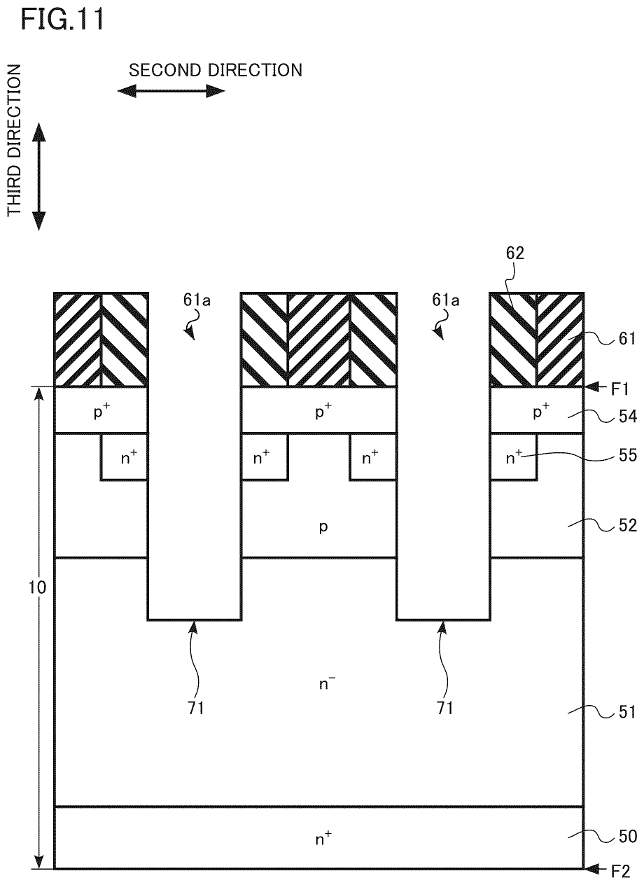

Then, using the first mask material 61 and the sidewall 62 as a mask, a trench 71 is formed (FIG. 11). The trench 71 penetrates the upper source region 53, the contact region 54, the lower source region 55, and the body region 52. The trench 71 is formed by using, for example, an RIE method.

The upper source region 53, the contact region 54, and the lower source region 55 are divided into left and right regions by the trench 71. The lower source region 55 is divided into two regions with the trench 71 interposed therebetween.

Then, a sidewall film 63 is formed on the side surface of the trench 71. The sidewall film 63 is, for example, a silicon oxide film.

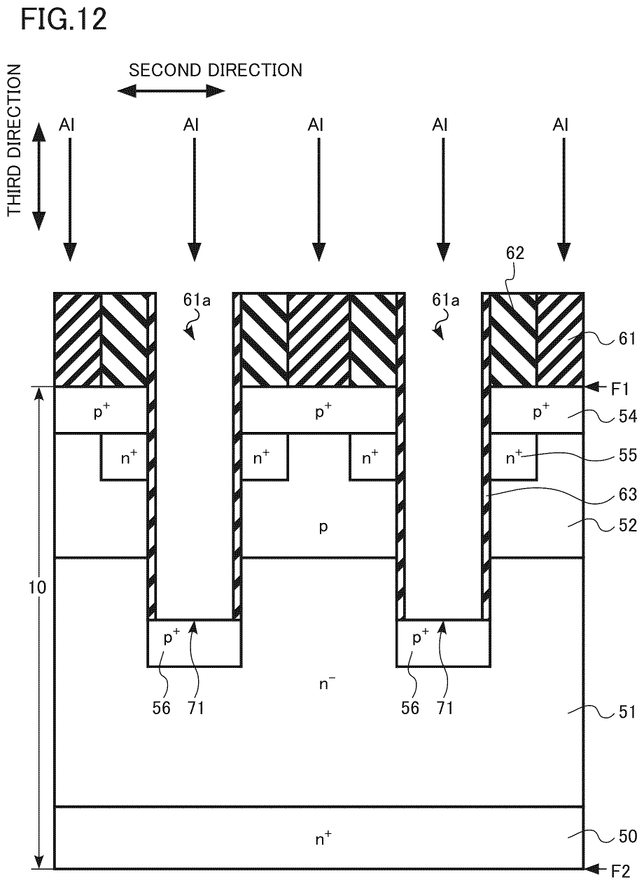

Then, using the first mask material 61 and the sidewall 62 as a mask, p-type impurities are ion-implanted to form the p⁺-type electric field relaxation region 56 (FIG. 12). The electric field relaxation region 56 is formed at the bottom of the trench 71. The p-type impurity is, for example, aluminum (Al). The sidewall film 63 suppresses the introduction of p-type impurities into the silicon carbide layer 10 from the side surface of the trench 71.

Then, the first mask material 61, the sidewall 62, and the sidewall film 63 are removed. The first mask material 61, the sidewall 62, and the sidewall film 63 are removed by using, for example, a wet etching method.

Then, a gate insulating layer 73 is formed in the trench 71. Then, a gate electrode 74 is formed on the gate insulating layer 73 in the trench 71. The gate insulating layer 73 is, for example, a silicon oxide film. The gate electrode 74 is, for example, polycrystalline silicon containing a p-type impurity or an n-type impurity. The gate insulating layer 73 and the gate electrode 74 are formed by using, for example, a CVD method.

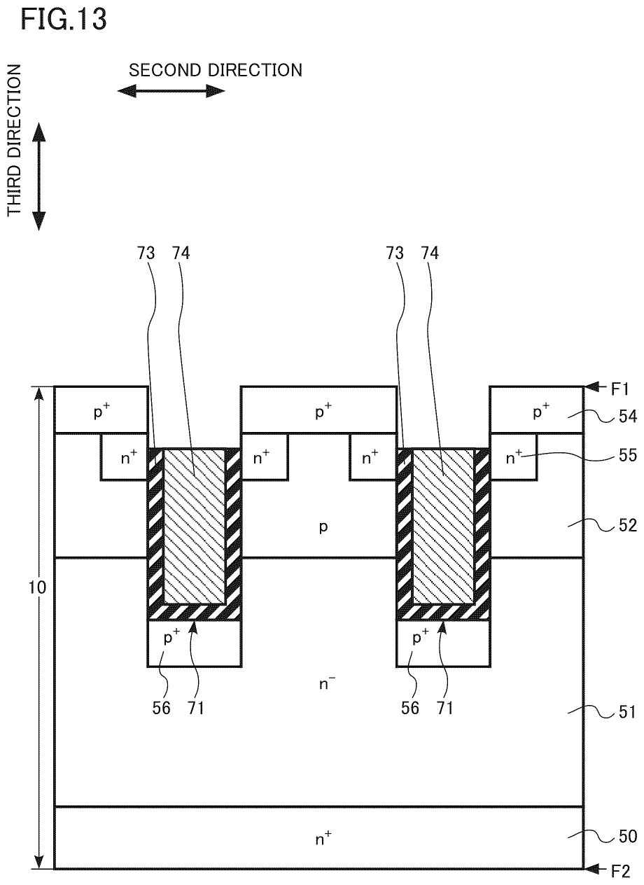

Then, the gate insulating layer 73 and the gate electrode 74 above the trench 71 are removed (FIG. 13). The gate insulating layer 73 and the gate electrode 74 are removed by using, for example, a wet etching method or a dry etching method. The top surface of the gate electrode 74 is disposed in the trench 71.

Then, the trench 71 is filled with a buried insulating layer 75. The buried insulating layer 75 is an example of an insulating layer. The buried insulating layer 75 is, for example, a silicon oxide film. The buried insulating layer 75 is formed by using, for example, a CVD method.

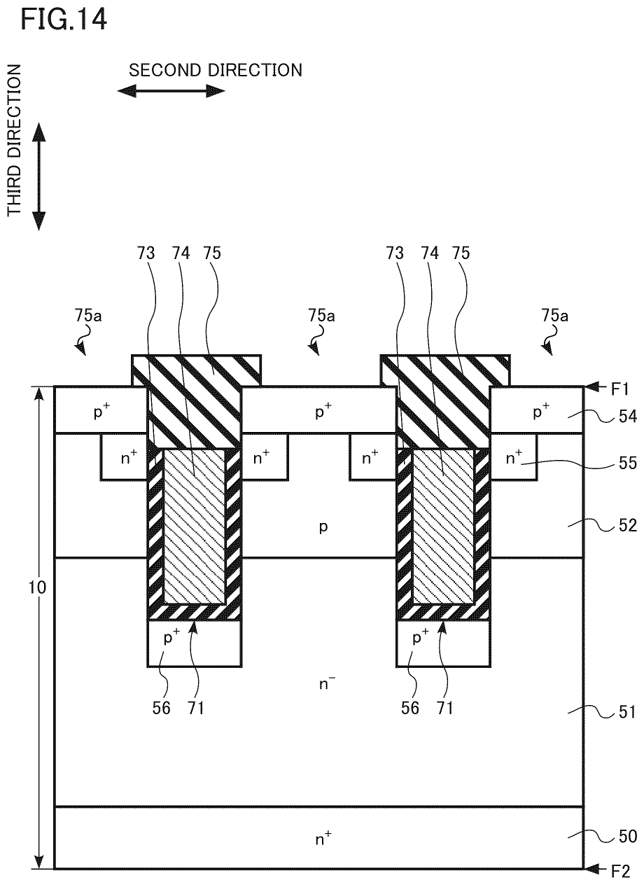

Then, a second opening 75a is formed in the buried insulating layer 75 (FIG. 14). In the second opening 75a, the upper source region 53 and the contact region 54 are exposed on the top surface of the silicon carbide layer 10. The second opening 75a is formed by using, for example, a photolithographic method and an RIE method.

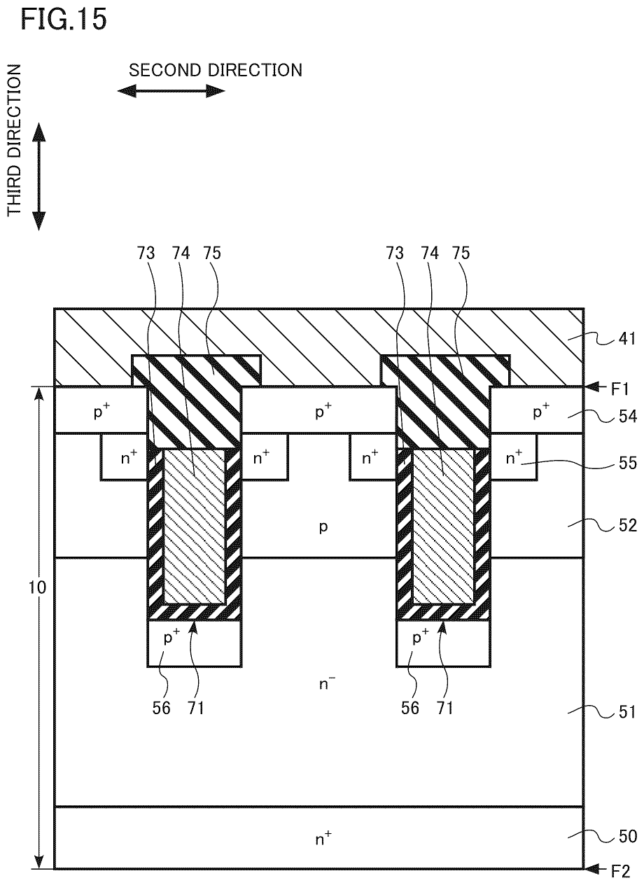

Then, the source electrode 41 is formed (FIG. 15). The source electrode 41 is formed by depositing a metal film using, for example, a sputtering method or a CVD method.

Thereafter, the drain electrode 42 is formed on the back surface of the silicon carbide layer 10 using a known process technique.

By the manufacturing method described above, the MOSFET 100 shown in FIGS. 1 to 4 is manufactured.

Next, the function and effect of the semiconductor device according to the first embodiment will be described.

According to the MOSFET 100 of the first embodiment, it is possible to achieve both a reduction in switching loss and a reduction in on-resistance. Hereinafter, detailed explanation will be given.

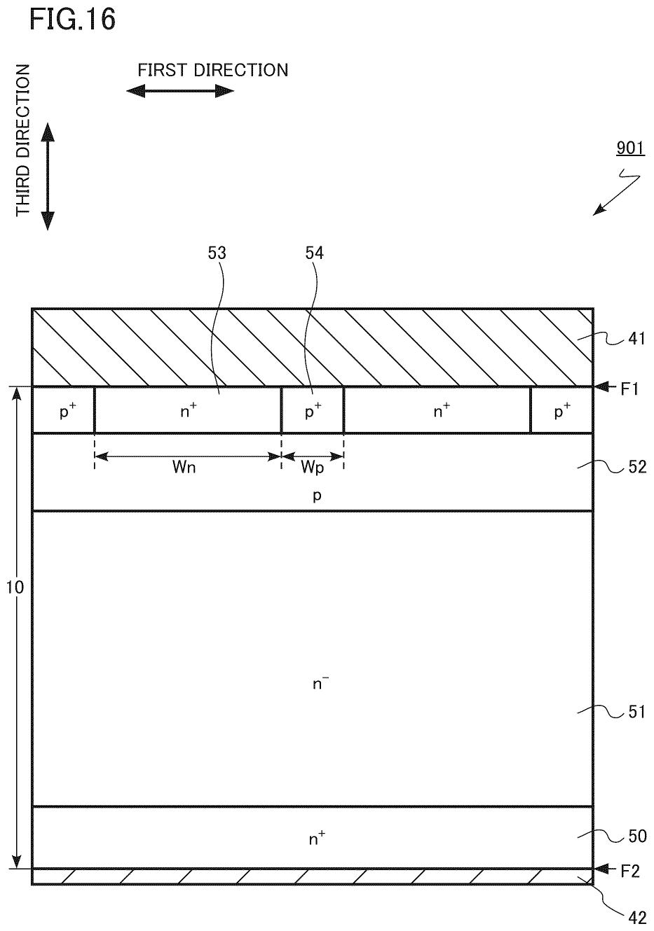

FIG. 16 is a schematic cross-sectional view of a semiconductor device according to a first comparative example. FIG. 16 is a diagram corresponding to FIG. 4 in the first embodiment.

The semiconductor device according to the first comparative example is a trench gate type vertical MOSFET 901 using silicon carbide. The MOSFET 901 is an n-channel MOSFET that uses electrons as carriers.

The MOSFET 901 is different from the MOSFET 100 according to the first embodiment in that the silicon carbide layer 10 does not include the n⁺-type lower source region 55.

In the MOSFET 901, the width Wn of the upper source region 53 in the first direction is larger than the width Wp of the contact region 54 in the first direction.

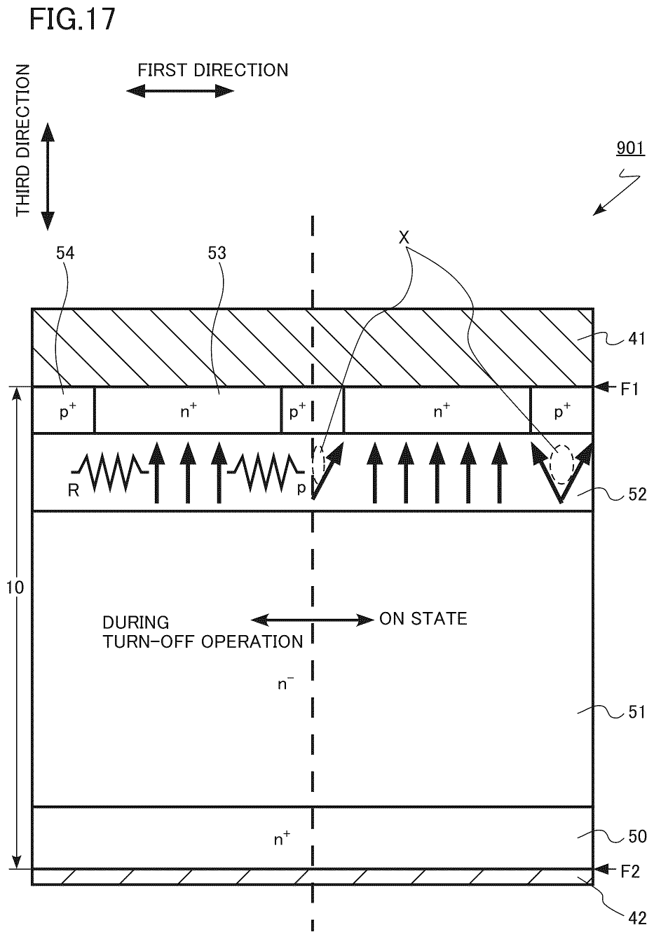

FIG. 17 is an explanatory diagram of a problem of the semiconductor device according to the first comparative example. FIG. 17 is a diagram corresponding to FIG. 16.

The right half of FIG. 17 schematically shows the current flowing in the body region 52 when the MOSFET 901 is in the ON state. The left half of FIG. 17 schematically shows the current flowing in the body region 52 during the turn-off operation of the MOSFET 901. In other words, the left half of FIG. 17 schematically shows the current flowing in the body region 52 when the MOSFET 901 transitions from the ON state to the OFF state. The current is indicated by arrows.

When the MOSFET 901 is in the ON state, the current flows through an inversion layer formed in the body region 52, from the drift region 51 toward the upper source region 53. At this time, the body region 52 between the contact region 54 and the drift region 51 becomes an inactive region (X in FIG. 17) where current is less likely to flow.

If the inactive region X exists in the body region 52, the channel resistance of the MOSFET 901 increases. Therefore, the on-resistance of the MOSFET 901 increases.

During the turn-off operation of the MOSFET 901, the inversion layer formed in the body region 52 disappears, causing the current to stop flowing and transitioning from the ON state to the OFF state. As shown in FIG. 17, the body region 52 between the center of the upper source region 53 and the drift region 51 is far from the contact region 54. For this reason, in the body region 52 between the central portion of the upper source region 53 and the drift region 51, the apparent resistance of the body region 52 increases to delay the change in potential during the turn-off operation. Therefore, the disappearance of the inversion layer in the body region 52 is delayed, and the transition from the ON state to the OFF state is delayed. Since the transition from the ON state to the OFF state is delayed, the turn-off loss of the MOSFET 901 increases. In other words, the switching loss of the MOSFET 901 increases.

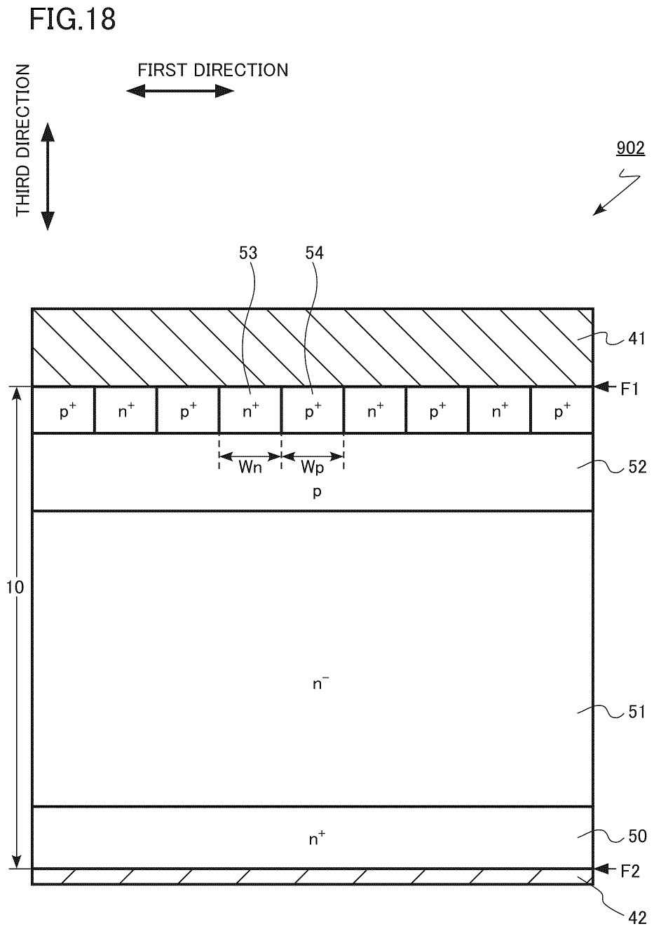

FIG. 18 is a schematic cross-sectional view of a semiconductor device according to a second comparative example. FIG. 18 is a diagram corresponding to FIG. 16 in the first comparative example.

The semiconductor device according to the second comparative example is a trench gate type vertical MOSFET 902 using silicon carbide. The MOSFET 902 is an n-channel MOSFET that uses electrons as carriers.

The MOSFET 902 is different from the MOSFET 901 in that the width Wn of the upper source region 53 in the first direction is smaller than that in the MOSFET 901 according to the first comparative example and the arrangement ratio (Wp/(Wn+Wp)) of the contact region 54 in the first direction is high.

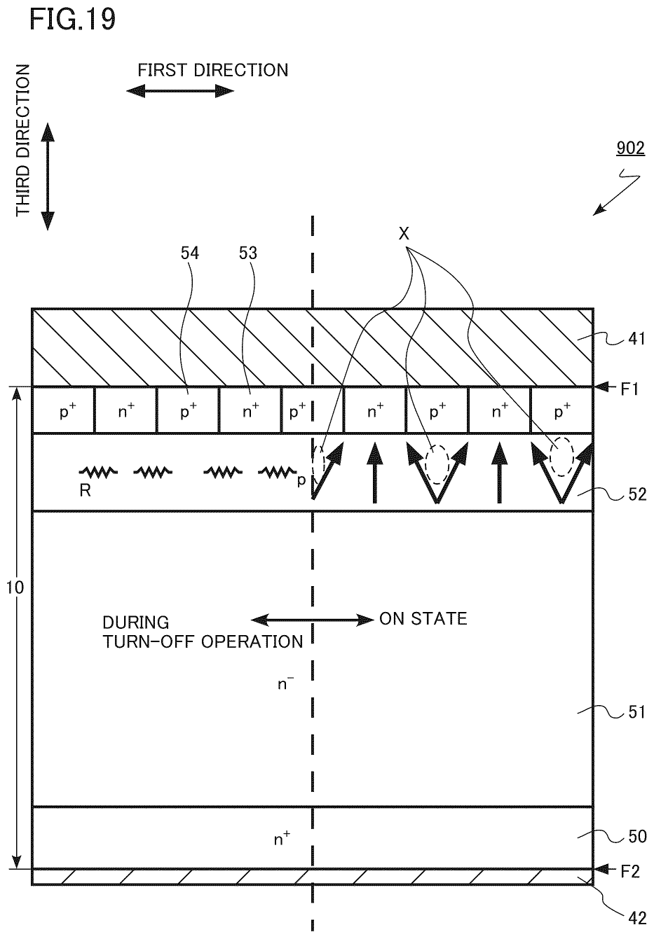

FIG. 19 is an explanatory diagram of a problem of the semiconductor device according to the second comparative example. FIG. 19 is a diagram corresponding to FIG. 18. FIG. 19 is a diagram corresponding to FIG. 17 in the first comparative example.

The right half of FIG. 19 schematically shows the current flowing in the body region 52 when the MOSFET 902 is in the ON state. The left half of FIG. 19 schematically shows the current flowing in the body region 52 during the turn-off operation of the MOSFET 902.

In the MOSFET 902, the width Wn of the upper source region 53 in the first direction is smaller than that in the MOSFET 901 according to the first comparative example. For this reason, the distance from the contact region 54 to the body region 52 between the central portion of the upper source region 53 and the drift region 51 is shorter than that in the MOSFET 901 according to the first comparative example. Therefore, in the body region 52 between the central portion of the upper source region 53 and the drift region 51, the apparent resistance of the body region 52 decreases to promote the change in potential during the turn-off operation. As a result, compared with the MOSFET 901 according to the first comparative example, the disappearance of the inversion layer is promoted, and the transition from the ON state to the OFF state is promoted. Since the transition from the ON state to the OFF state is promoted, the turn-off loss of the MOSFET 902 is reduced. In other words, the switching loss of the MOSFET 902 is reduced.

When the MOSFET 902 is in the ON state, the current flows through an inversion layer formed in the body region 52, from the drift region 51 toward the upper source region 53. At this time, the body region 52 between the contact region 54 and the drift region 51 becomes an inactive region X where current is less likely to flow.

If the inactive region X exists in the body region 52, the channel resistance of the MOSFET 902 increases. Therefore, the on-resistance of the MOSFET 902 increases.

The MOSFET 902 has a higher arrangement ratio of the contact region 54 than in the MOSFET 901 according to the first comparative example. For this reason, the proportion of the inactive region X where current is less likely to flow in the body region 52 is higher than in the MOSFET 901 according to the first comparative example. Therefore, the channel resistance of the MOSFET 902 is larger than that in the MOSFET 901 according to the first comparative example. As a result, the on-resistance of the MOSFET 902 is larger than that of the MOSFET 901 according to the first comparative example.

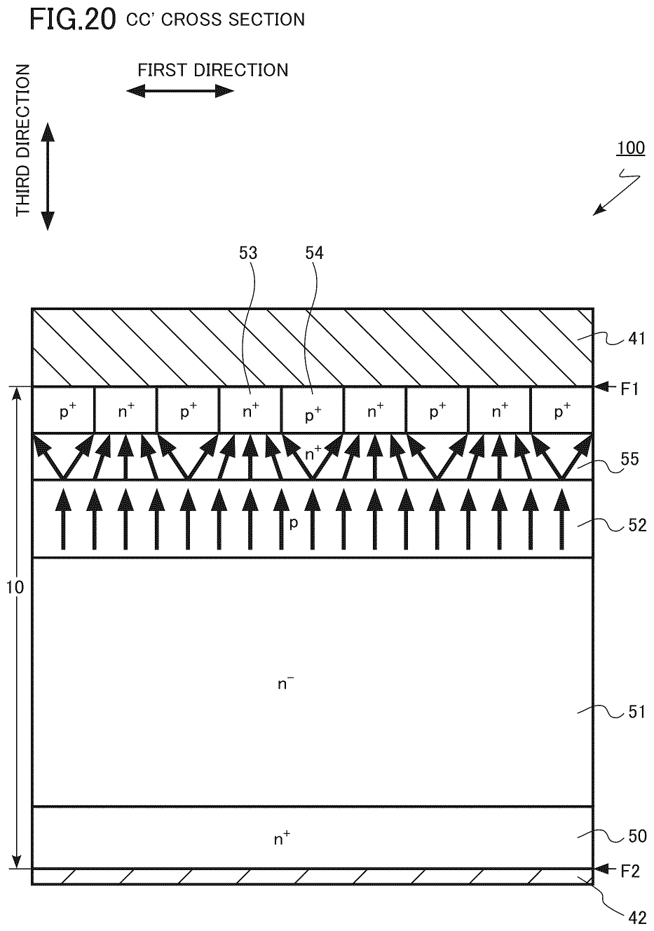

FIG. 20 is an explanatory diagram of the function and effect of the semiconductor device according to the first embodiment. FIG. 20 is a diagram corresponding to FIG. 4.

FIG. 20 schematically shows the current flowing in the body region 52 when the MOSFET 100 is in the ON state. The current is indicated by arrows.

The MOSFET 100 according to the first embodiment is different from the MOSFET 902 according to the second comparative example in that the MOSFET 100 includes the n⁺-type lower source region 55. The MOSFET 100 according to the first embodiment includes the lower source region 55 between the contact region 54 and the body region 52. This reduces the resistance below the contact region 54, making it easier for current to flow. Therefore, within the body region 52, there is almost no inactive region where current is less likely to flow. As a result, the on-resistance of the MOSFET 100 is reduced.

According to the MOSFET 100 of the first embodiment, it is possible to achieve both a reduction in switching loss and a reduction in on-resistance.

In the case of a MOSFET that does not include the lower source region 55, the larger the arrangement ratio (Wp/(Wn+Wp)) of the contact region 54 in the first direction, the larger the proportion of the inactive region in the body region 52, and the higher the channel resistance. Therefore, providing the lower source region 55 is effective especially when the arrangement ratio (Wp/(Wn+Wp)) of the contact region 54 in the first direction is large. In other words, the arrangement ratio (Wp/(Wn+Wp)) of the contact region 54 in the first direction is, a ratio (Wp/(Wn+Wp)) of the width Wp of the contact region 54 in the first direction to the sum of the width Wn of the upper source region 53 in the first direction and the width Wp of the contact region 54 in the first direction.

From the above perspective, the arrangement ratio (Wp/(Wn+Wp)) of the contact region 54 in the first direction is preferably equal to or more than 0.1, more preferably equal to or more than 1, and even more preferably equal to or more than 10.

From the viewpoint of reducing the electrical resistance of the lower source region 55 and reducing the on-resistance of the MOSFET 100, the n-type impurity concentration of the lower source region 55 is, for example, preferably equal to or more than 1×10¹⁹ cm⁻³, more preferably equal to or more than 5×10¹⁹ cm⁻³, and even more preferably equal to or more than 1×10²⁰ cm⁻³.

From the viewpoint of reducing the electrical resistance of the lower source region 55 in the vertical direction (third direction) and reducing the on-resistance of the MOSFET 100, the width of the lower source region 55 in the third direction is preferably equal to or less than 0.6 μm.

From the viewpoint of reducing the electrical resistance of the lower source region 55 in the lateral direction (first direction) and reducing the on-resistance of the MOSFET 100, the width of the lower source region 55 in the third direction is preferably equal to or more than 0.2 μm.

The n-type impurity concentration of the lower source region 55 is preferably equal to or more than 0.1 times and equal to or less than 10 times the n-type impurity concentration of the upper source region 53, more preferably equal to or more than 0.2 times and equal to or less than 5 times, and even more preferably equal to or more than 0.5 times and equal to or less than 2 times.

From the viewpoint of increasing the arrangement ratio of the upper source region 53 in the first direction and reducing the on-resistance of the MOSFET 100, the arrangement ratio (Wp/(Wn+Wp)) of the contact region 54 in the first direction is preferably equal to or less than 50, more preferably equal to or less than 5, and even more preferably equal to or less than 2.

As described above, according to the first embodiment, it is possible to realize a MOSFET that can achieve both a reduction in switching loss and a reduction in on-resistance.

### Second Embodiment

A semiconductor device according to a second embodiment is different from the semiconductor device according to the first embodiment in that the first electrode is in contact with the side surface of the first trench and the side surface of the second trench. Hereinafter, the description of a part of the content overlapping the first embodiment may be omitted.

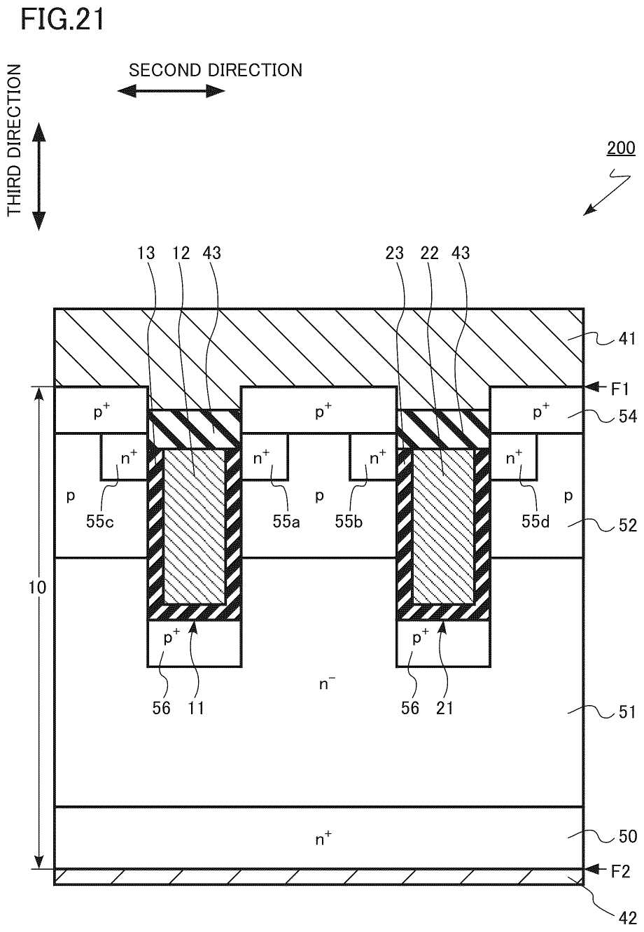

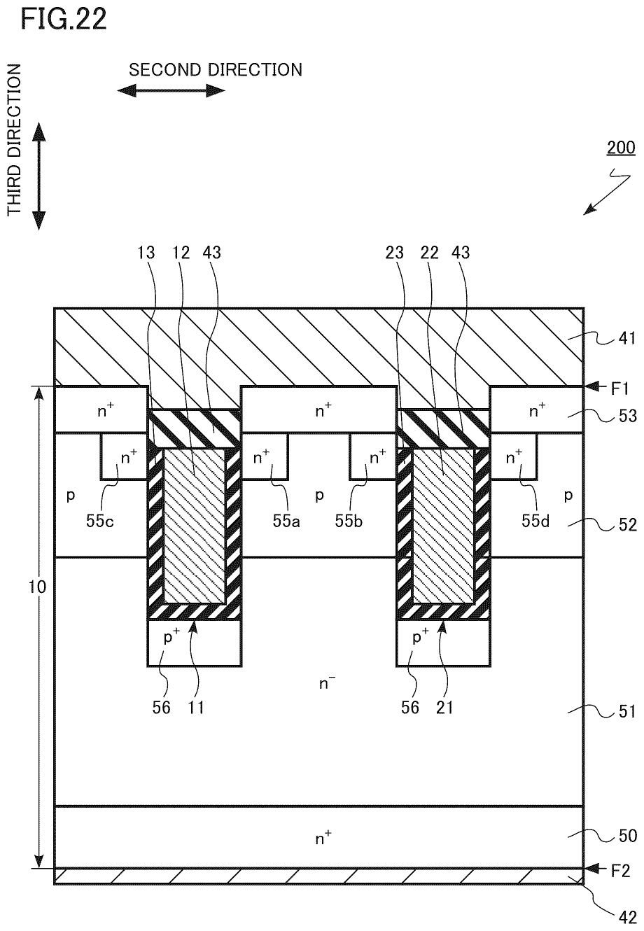

FIGS. 21 and 22 are schematic cross-sectional views of the semiconductor device according to the second embodiment. The semiconductor device according to the second embodiment is a trench gate type vertical MOSFET 200 using silicon carbide. The MOSFET 200 is an n-channel MOSFET that uses electrons as carriers.

FIG. 21 is a diagram corresponding to FIG. 1 in the first embodiment. FIG. 22 is a diagram corresponding to FIG. 3 in the first embodiment.

The MOSFET 200 includes a silicon carbide layer 10, a first trench 11, a first gate electrode 12, a first gate insulating layer 13, a second trench 21, a second gate electrode 22, a second gate insulating layer 23, a source electrode 41 (first electrode), a drain electrode 42 (second electrode), and an interlayer insulating layer 43.

In the silicon carbide layer 10, an n⁺-type drain region 50, an n⁻-type drift region 51 (first silicon carbide region), a p-type body region 52 (second silicon carbide region), an n⁺-type upper source region 53 (third silicon carbide region), a p⁺-type contact region 54 (fourth silicon carbide region), a first lower source region 55a (fifth silicon carbide region) of n⁺-type, a second lower source region 55b (sixth silicon carbide region) of n⁺-type, a third lower source region 55c of n⁺-type, a fourth lower source region 55d of n⁺-type, and a p⁺-type electric field relaxation region 56 are provided.

The source electrode 41 is provided on the surface side of the silicon carbide layer 10. The source electrode 41 is in contact with the side surface of the first trench 11. The source electrode 41 is in contact with the upper source region 53 and the contact region 54 on the side surface of the first trench 11.

The source electrode 41 is in contact with the side surface of the second trench 21. The source electrode 41 is in contact with the upper source region 53 and the contact region 54 on the side surface of the second trench 21.

The source electrode 41 is in contact with the upper source region 53 and the contact region 54 on the surface of the silicon carbide layer 10.

The MOSFET 200 according to the second embodiment can be manufactured by etching the buried insulating layer 75 filled in the trench 71 so that a part of the side surface of the trench 71 is exposed before the source electrode 41 is formed in the semiconductor device manufacturing method according to the first embodiment.

According to the MOSFET 200 of the second embodiment, the contact resistance of the source electrode 41 is reduced compared to the MOSFET 100 according to the first embodiment. Therefore, in the MOSFET 200 according to the second embodiment, it is possible to reduce the on-resistance more than in the MOSFET 100.

### Modification Example

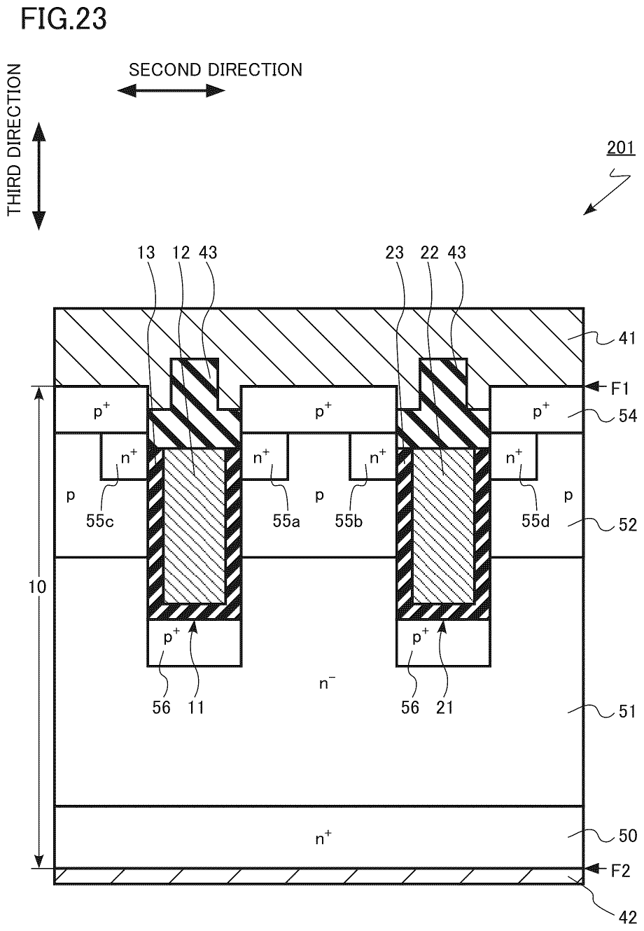

FIG. 23 is a schematic cross-sectional view of a semiconductor device according to a modification example of the second embodiment. FIG. 23 is a diagram corresponding to FIG. 21 in the second embodiment.

A MOSFET 201 according to the modification example is different from the MOSFET 200 according to the second embodiment in that a part of the interlayer insulating layer 43 is present above the first face F1 of the silicon carbide layer 10.

As described above, according to the second embodiment and its modification example, it is possible to realize a MOSFET that can achieve both a reduction in switching loss and a reduction in on-resistance.

### Third Embodiment

An inverter circuit and a drive device according to a third embodiment are an inverter circuit and a drive device including the semiconductor device according to the first embodiment.

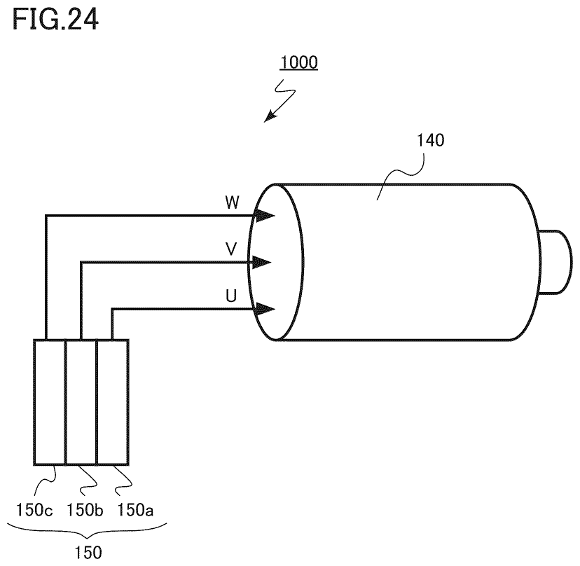

FIG. 24 is a schematic diagram of the drive device according to the third embodiment. A drive device 1000 includes a motor 140 and an inverter circuit 150.

The inverter circuit 150 includes three semiconductor modules 150a, 150b, and 150c having the MOSFET 100 according to the first embodiment as a switching element. By connecting the three semiconductor modules 150a, 150b, and 150c in parallel to each other, a three-phase inverter circuit 150 having three AC voltage output terminals U, V, and W is realized. The motor 140 is driven by the AC voltage output from the inverter circuit 150.

According to the third embodiment, the characteristics of the inverter circuit 150 and the drive device 1000 are improved by providing the MOSFET 100 with improved characteristics.

### Fourth Embodiment

A vehicle according to a fourth embodiment is a vehicle including the semiconductor device according to the first embodiment.

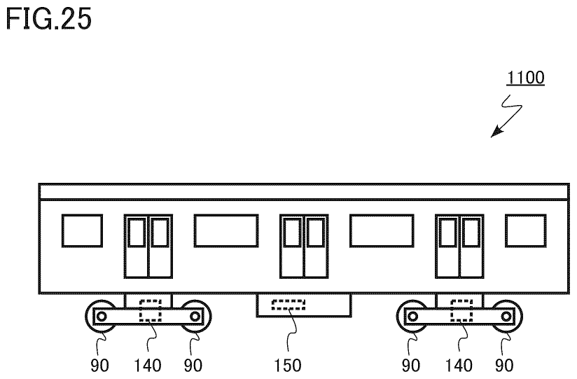

FIG. 25 is a schematic view of the vehicle according to the fourth embodiment. A vehicle 1100 according to the fourth embodiment is a railroad vehicle. The vehicle 1100 includes a motor 140 and an inverter circuit 150.

The inverter circuit 150 includes three semiconductor modules having the MOSFET 100 according to the first embodiment as a switching element. By connecting the three semiconductor modules in parallel to each other, a three-phase inverter circuit 150 having three AC voltage output terminals U, V, and W is realized. The motor 140 is driven by the AC voltage output from the inverter circuit 150. The motor 140 rotates wheels 90 of the vehicle 1100.

According to the fourth embodiment, the characteristics of the vehicle 1100 are improved by providing the MOSFET 100 with improved characteristics.

### Fifth Embodiment

A vehicle according to a fifth embodiment is a vehicle including the semiconductor device according to the first embodiment.

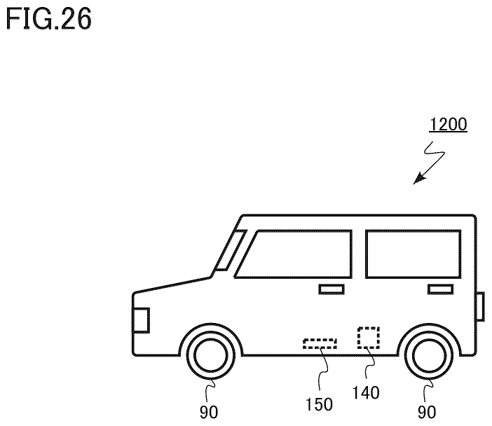

FIG. 26 is a schematic diagram of the vehicle according to the fifth embodiment. A vehicle 1200 according to the fifth embodiment is an automobile. The vehicle 1200 includes a motor 140 and an inverter circuit 150.

The inverter circuit 150 includes three semiconductor modules having the MOSFET 100 according to the first embodiment as a switching element. By connecting the three semiconductor modules in parallel to each other, a three-phase inverter circuit 150 having three AC voltage output terminals U, V, and W is realized.

The motor 140 is driven by the AC voltage output from the inverter circuit 150. The motor 140 rotates wheels 90 of the vehicle 1200.

According to the fifth embodiment, the characteristics of the vehicle 1200 are improved by providing the MOSFET 100 with improved characteristics.

### Sixth Embodiment

An elevator according to a sixth embodiment is an elevator including the semiconductor device according to the first embodiment.

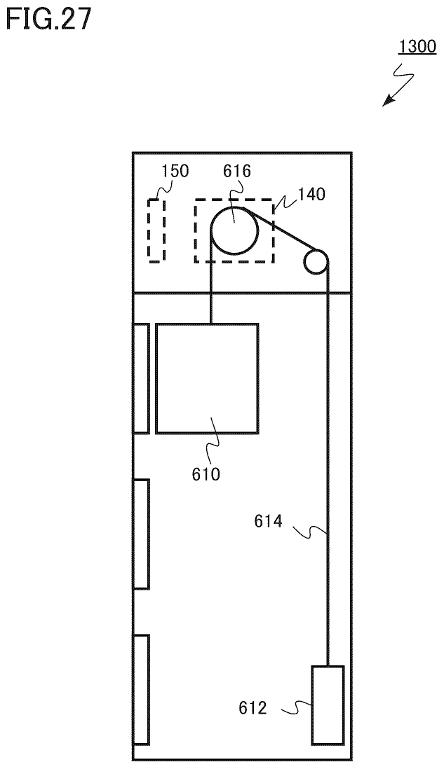

FIG. 27 is a schematic diagram of the elevator according to the sixth embodiment. An elevator 1300 according to the sixth embodiment includes a car 610, a counterweight 612, a wire rope 614, a hoisting machine 616, a motor 140, and an inverter circuit 150.

The inverter circuit 150 includes three semiconductor modules having the MOSFET 100 according to the first embodiment as a switching element. By connecting the three semiconductor modules in parallel to each other, a three-phase inverter circuit 150 having three AC voltage output terminals U, V, and W is realized.

The motor 140 is driven by the AC voltage output from the inverter circuit 150. The hoisting machine 616 is rotated by the motor 140, and as a result, the car 610 moves up and down.

According to the sixth embodiment, the characteristics of the elevator 1300 are improved by providing the MOSFET 100 with improved characteristics.

As described above, in the first and second embodiments, the case of 4H-SiC has been described as an example of the crystal structure of silicon carbide. However, embodiments can also be applied to silicon carbide having other crystal structures, such as 6H-SiC and 3C-SiC.

In the first and second embodiments, a MOSFET has been described as an example of the semiconductor device. However, embodiments can also be applied to an insulated gate bipolar transistor (IGBT). For example, the IGBT can be realized by replacing a region corresponding to the drain region 50 of the MOSFET 100 from n-type to p-type.

In addition, in the third to sixth embodiments, the case where the semiconductor device according to the first embodiment is provided has been described as an example. However, the semiconductor device according to the second embodiment or its modification example can also be applied.

In addition, in the third to sixth embodiments, the cases where the semiconductor devices of embodiments are applied to a vehicle or an elevator have been described as examples. However, the semiconductor devices of embodiments can also be applied to, for example, a power conditioner of a photovoltaic power generation system.

While certain embodiments have been described, these embodiments have been presented by way of example only, and are not intended to limit the scope of the inventions. Indeed, the semiconductor device, the semiconductor device manufacturing method, the inverter circuit, the drive device, the vehicle, and the elevator described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device, comprising:
a silicon carbide layer having a first face parallel to a first direction and a second direction perpendicular to the first direction and a second face parallel to the first face;
a first trench provided in the silicon carbide layer, provided on a side of the first face of the silicon carbide layer, and extending in the first direction;
a first gate electrode provided in the first trench;
a first gate insulating layer provided between the first gate electrode and the silicon carbide layer;
a second trench provided in the silicon carbide layer, provided on the side of the first face of the silicon carbide layer, and extending in the first direction;
a second gate electrode provided in the second trench;
a second gate insulating layer provided between the second gate electrode and the silicon carbide layer;
a first silicon carbide region of n-type provided in the silicon carbide layer, at least a part of the first silicon carbide region of n-type being provided between the first trench and the second trench;
a second silicon carbide region of p-type provided in the silicon carbide layer, provided between the first trench and the second trench, and provided between the first silicon carbide region and the first face;
a plurality of third silicon carbide regions of n-type and a plurality of fourth silicon carbide regions of p-type provided in the silicon carbide layer, provided between the first trench and the second trench, provided between the second silicon carbide region and the first face, and arranged alternately in the first direction;
a fifth silicon carbide region of n-type provided in the silicon carbide layer, provided between the first trench and the second trench, in contact with the first trench, provided between the second silicon carbide region and the third silicon carbide region and between the second silicon carbide region and the fourth silicon carbide region, and extending in the first direction;
a sixth silicon carbide region of n-type provided in the silicon carbide layer, provided between the first trench and the second trench, in contact with the second trench, spaced apart from the fifth silicon carbide region, provided between the second silicon carbide region and the third silicon carbide region and between the second silicon carbide region and the fourth silicon carbide region, and extending in the first direction;
a first electrode provided on a side of the first face with respect to the silicon carbide layer and in contact with the third silicon carbide region and the fourth silicon carbide region;
a second electrode provided on a side of the second face with respect to the silicon carbide layer; and
an interlayer insulating layer provided between the first gate electrode and the first electrode and between the second gate electrode and the first electrode.

2. The semiconductor device according to claim 1,
wherein the third silicon carbide region and the fourth silicon carbide region are in contact with the first trench and the second trench.

3. The semiconductor device according to claim 1,
wherein the fifth silicon carbide region is in contact with the third silicon carbide region and the fourth silicon carbide region, and
the sixth silicon carbide region is in contact with the third silicon carbide region and the fourth silicon carbide region.

4. The semiconductor device according to claim 1,
wherein the second silicon carbide region is provided between the fifth silicon carbide region and the sixth silicon carbide region.

5. The semiconductor device according to claim 1,
wherein a p-type impurity concentration of the fourth silicon carbide region is higher than a p-type impurity concentration of the second silicon carbide region.

6. The semiconductor device according to claim 1,
wherein an n-type impurity concentration of the fifth silicon carbide region and an n-type impurity concentration of the sixth silicon carbide region are equal to or more than 0.1 times and equal to or less than 10 times an n-type impurity concentration of the third silicon carbide region.

7. The semiconductor device according to claim 1,
wherein a distance in a third direction perpendicular to the first face from the first face to the first gate electrode is larger than a distance in the third direction from the first face to an interface between the fourth silicon carbide region and the fifth silicon carbide region.

8. The semiconductor device according to claim 1,
wherein the first electrode is in contact with a side surface of the first trench and a side surface of the second trench.

9. The semiconductor device according to claim 1,
wherein a ratio of a width of the fourth silicon carbide region in the first direction to a sum of a width of the third silicon carbide region in the first direction and a width of the fourth silicon carbide region in the first direction is equal to or more than 0.1 and equal to or less than 50.

10. An inverter circuit, comprising:
the semiconductor device according to claim 1.

11. A drive device, comprising:
the semiconductor device according to claim 1.

12. A vehicle, comprising:
the semiconductor device according to claim 1.

13. An elevator, comprising:
the semiconductor device according to claim 1.

14. A semiconductor device manufacturing method, comprising:
preparing a silicon carbide layer having a first face parallel to a first direction and a second direction perpendicular to the first direction and a second face parallel to the first face and including a first region of n-type, a second region of p-type provided between the first region and the first face, and a plurality of third regions of n-type and a plurality of fourth regions of p-type provided between the second region and the first face, arranged alternately in the first direction, and extending in the second direction;
forming a first mask material having a first opening extending in the first direction on the silicon carbide layer;
forming a fifth region of n-type deeper than the third region and the fourth region and shallower than the second region by ion-implanting n-type impurities through the first opening using the first mask material as a mask;
forming a sidewall at the first opening;
forming a trench penetrating the second region, the third region, the fourth region, and the fifth region using the first mask material and the sidewall as a mask;
forming a gate insulating layer in the trench; and
forming a gate electrode on the gate insulating layer in the trench.

15. The semiconductor device manufacturing method according to claim 14,
wherein a top surface of the gate electrode is disposed within the trench.

16. The semiconductor device manufacturing method according to claim 14, further comprising:
filling the trench above the gate electrode with an insulating layer after the forming the gate electrode;
etching the insulating layer so that at least a part of a side surface of the trench is exposed; and
forming an electrode in contact with the third region and the fourth region on the side surface of the trench.
